(19) United States
(12) Patent Application Publication
(10) Pub. No.: US 2012/0192026 A1
(43) Pub. Date: Jul. 26, 2012

(54) Methods and Systems for Data Transmission Management Using HARQ Mechanism for Concatenated Coded System

(75) Inventors: Ren-Jr Chen, Hsinchu City (TW); Hua-Lung Yang, Taipei City (TW); Chien-Min Lee, New Taipei City (TW); Chia-Wen Hsieh, Chiayi City (TW); Chang-Lung Hsiao, Zhubei City (TW)

(73) Assignee: INDUSTRIAL TECHNOLOGY RESEARCH INSTITUTE, Chutung (TW)

(21) Appl. No.: 13/183,832

(22) Filed: Jul. 15, 2011

Related U.S. Application Data
(60) Provisional application No. 61/365,168, filed on Jul. 16, 2010.

(51) Int. Cl. H04L 1/18; G06F 11/14; H03M 13/05; G06F 11/10

(52) U.S. Cl. 714/751; 714/E11.032; 714/E11.131

(57) ABSTRACT

Methods for data transmission management used in a transmitter are provided. The method comprises the steps of: encoding M uncoded packets into N coded packets with Q-packet error correction capability using concatenated encoding, where M≦N, and Q≧1; sequentially transmitting a set or all of the N coded packets to the at least one receiver; receiving at least one feedback information from the at least one receiver, wherein the at least one feedback information comprises at least one ACK or NACK information for indicating decoding statuses of the transmitted coded packets, each of the transmitted coded packets having one of the decoding statuses corresponding thereto; and determining whether to perform a retransmission procedure to retransmit a dedicated packet to the at least one receiver according to collected ACK/NACK included in the feedback information.

### CROSS REFERENCE TO RELATED APPLICATIONS

This application claims priority to U.S. Provisional Application No. 61/365,168, filed on Jul. 16, 2010, the entirety of which is incorporated by reference herein

### BACKGROUND OF THE DISCLOSURE

1. Field of the Disclosure

The disclosure relates generally to data transmission management and data transmission management systems thereof, and more particularly, to data transmission management systems and methods for data transmission management using Hybrid Automatic Repeat ReQuest (HARQ) Mechanism for Concatenated Coded System.

2. Description of the Related Art

In communication systems, a base station may communicate with more than one mobile station (MS) at the same time. The mobile stations are commonly referred to as User equipments (UEs). The UE may communicate voice and/or data signals with one or more service networks via base stations of the service networks. The wireless communications between the UE and the base stations of service networks may be in compliance with various wireless technologies, such as the Global System for Mobile communications (GSM) technology, General Packet Radio Service (GPRS) technology, Enhanced Data rates for Global Evolution (EDGE) technology, Wideband Code Division Multiple Access (WCDMA) technology, Code Division Multiple Access 2000 (CDMA 2000) technology, Time Division-Synchronous Code Division Multiple Access (TD-SCDMA) technology, and Worldwide Interoperability for Microwave Access (WiMAX) technology and others.

In some such networks (e.g. a WiMAX network), communications between transmitters (e.g. BSs) and receivers (e.g. UEs) is subjected to interference and loss of data being communicated. A technique referred to as Hybrid Automatic Repeat ReQuest (HARQ or Hybrid ARQ) is therefore sometimes employed. The HARQ or Hybrid ARQ is a mechanism to improve transmission reliability. It is a variation of the automatic repeat request (ARQ) error control method for data transmission. In the hybrid ARQ, both the error checking scheme (such as cyclic redundancy check, CRC) and the error correction scheme (forward-error-correction, such as Turbo, convolution, and Reed-Solomon code) are applied to report on a detection status of a UE. For example, for the ARQ, redundancy bits or error correction bits are attached to data (such as cyclic redundancy check, CRC) to confirm whether received information is correct. When the UE receives a transmission, the UE may use the error detection bits to determine if data has been lost so as to determine whether the data has been successfully detected. If a UE does not successfully receive the data information and the retransmission number is smaller than the pre-defined maximum retransmission number, the BS will retransmit the packet. When the UE receives a retransmitted packet, the UE may combine the new packet with the old one (referred to as soft combining). The UE may store the combined packet unless detection is corrected or the retransmission number is equal to a maximum retransmission time. The coded bits are divided into several sub-bit-streams based on redundancy version selection. If a receiver (such as the UE) successfully receives the downlink information, the receiver will send an acknowledgment (ACK) to the transmitter (such as BS). If the receiver fails to detect the downlink information, the receiver will send a negative acknowledgment (NACK) to the transmitter. Meanwhile, if the transmitter does not receive an acknowledgment or receives a negative acknowledgment before timeout, it will retransmit the data information. If the BS detects an NACK on a packet, the BS may retransmit another redundancy version of the packet to the UE until the BS detects an ACK on any redundancy version of the packet or achieves the maximum retransmission number.

To achieve better coding performance, the communication systems could perform a concatenated encoding method instead of single encoding scheme. The concatenated encoding method comprises two encoding schemes: horizontal coding scheme (channel coding) and vertical coding scheme. Further, a vertical coding scheme could be performed before or after a channel coding. In a first case, the communication system may perform an additional coding scheme before channel coding. In this case, the additional coding scheme encodes M bits which come from each bit-stream. Channel coding encodes the bit-stream when the vertical encoding procedure is finished. Assuming that M transport-blocks (TB) are to be encoded, there are N (M N) bit-streams after vertical encoding and N codewords after channel coding. In a second case, the communication system may perform an additional coding scheme after channel coding. In this case, channel coding encoding the bit-stream comes from the CRC attachment. The additional coding scheme encodes M bits which come from each codeword. Similarly, if M transport-blocks (TB) are to be encoded, there are M codewords after the channel coding and N (M N) packets left after the concatenated encoding. Note that CRC attachment and concatenated encoding should be performed on each transport-block in both cases.

When the aforementioned concatenated coding scheme is applied to encode M transport blocks, N packets may be generated after concatenated encoding. It is assumed that the error correct capability of the additional forward-error-correction (FEC) scheme is Q bits. In other words, the additional error decoder could detect received packets correctly when the number of error bits is less than or equal to Q. Therefore, the error packets may be correctly decoded when the number of error packets is less than or equal to Q. On the contrary, however, the errors may not be corrected when the number of error packets is larger than Q. Therefore, the HARQ feedback scheduling method should be redesigned when the concatenated coding scheme is applied.

### SUMMARY

Data transmission management systems and methods for data transmission management used in a transmitter are provided.

In one exemplary embodiment, a method for data transmission management used in a transmitter is provided. First, M uncoded packets are encoded into N coded packets with Q-packet error correction capability using concatenated encoding, wherein the M uncoded packets are first encoded by a first encoding scheme and then encoded into N coded packets by a second encoding scheme and where M≦N, and Q≧1. A set or all of the N coded packets are sequentially transmitted to the at least one receiver. Thereafter, at least one feedback information is received from the at least one receiver, wherein the at least one feedback information comprises at least one acknowledgment (ACK) or negative acknowledgment (NACK) information for indicating decoding statuses of the transmitted coded packets, each of the transmitted coded packets having one of the decoding statuses corresponding thereto. It is then determined whether to perform a retransmission procedure to retransmit a dedicated packet to the at least one receiver according to collected ACK/NACK included in the feedback information.

An exemplary embodiment of a data transmission management system comprises at least a receiver and a transmitter. The at least one receiver is wirelessly connected to the transmitter for performing wireless operations. The transmitter encodes M uncoded packets into N coded packets with Q-packet error correction capability using concatenated encoding, wherein the M uncoded packets are first encoded by a first encoding scheme and then encoded into N coded packets by a second encoding scheme and where M≦N, and Q≧1, sequentially transmits a set or all of the N coded packets to the at least one receiver, receives at least one feedback information from the at least one receiver, wherein the at least one feedback information comprises at least one acknowledgment (ACK) or negative acknowledgment (NACK) information for indicating decoding statuses of the transmitted coded packets, each of the transmitted coded packets having one of the decoding statuses corresponding thereto, and determines whether to perform a retransmission procedure to retransmit a dedicated packet to the at least one receiver according to collected ACK/NACK included in the feedback information.

Methods for data transmission management used in a transmitter may take the form of a program code embodied in a tangible media. When the program code is loaded into and executed by a machine, the machine becomes an apparatus for practicing the disclosed method.

### BRIEF DESCRIPTION OF THE DRAWINGS

The disclosure will become more fully understood by referring to the following detailed description with reference to the accompanying drawings, wherein:

FIG. 1 is a block diagram illustrating a data transmission management system according to an embodiment of the disclosure;

FIG. 2 is a schematic diagram illustrating a flowchart of a method for data transmission management used in multiple-user scenarios according to an embodiment of the disclosure;

FIG. 3 is a schematic diagram illustrating a flowchart of a method for data transmission management used in multiple-user scenarios according to another embodiment of the disclosure;

FIG. 4 is a schematic diagram illustrating a flowchart of a method for data transmission management used in single user scenarios according to yet another embodiment of the disclosure; and

FIGS. 5-11 are schematic diagrams illustrating exemplary embodiments of a HARQ feedback scheduling method in single-user and multiple-user scenarios according to yet another embodiment of the disclosure.

### DETAILED DESCRIPTION OF THE DISCLOSURE

The following description is of the best-contemplated mode of carrying out the disclosure. This description is made for the purpose of illustrating the general principles of the disclosure and should not be taken in a limiting sense. The scope of the disclosure is best determined by reference to the appended claims.

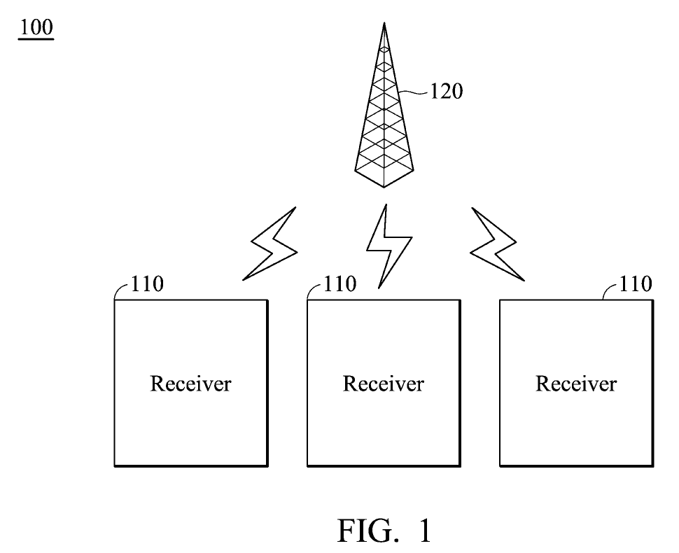

FIG. 1 is a block diagram illustrating a data transmission management system according to an embodiment of the disclosure. In the data transmission management system 100, one or more receivers 110 (e.g. mobile communications devices) are wirelessly connected to a transmitter 120 (e.g. a base station serving the mobile communications devices) to obtain wireless services. Generally, the receiver 110 may be referred to as a User Equipment (UE) and the transmitter 120 may be referred to as a base station, an access station and so on. The receiver 110 comprises a wireless module (not shown) for performing the functionality of wireless transmission and receptions to and from the transmitter. To further clarify, the wireless module may comprise a baseband unit (not shown) and a radio frequency (RF) unit (not shown). The baseband unit may contain multiple hardware devices to perform baseband signal processing, including analog to digital conversion (ADC)/digital to analog conversion (DAC), gain adjusting, modulation/demodulation, encoding/decoding, and so on. The RF unit may receive RF wireless signals, convert the received RF wireless signals to baseband signals, which are processed by the baseband unit, or receive baseband signals from the baseband unit and convert the received baseband signals to RF wireless signals, which are later transmitted. The RF unit may also contain multiple hardware devices to perform radio frequency conversion. For example, the RF unit may comprise a mixer to multiply the baseband signals with a carrier oscillated in the radio frequency of the wireless communication system, wherein the radio frequency may be 900 MHz, 1900 MHz, or 2100 MHz utilized in WCDMA systems, or others depending on the radio access technology (RAT) in use. Also, the receiver 110 further comprises a controller module (not shown) for controlling the operation of the wireless module and other functional components, such as a display unit and/or keypad serving as the MMI (man-machine interface), a storage unit storing the program codes of applications or communication protocols, or others. The operation of the receiver 110 and the transmitter 120 is in compliance with a communication protocol. For example, in one embodiment, the transmitter 120 may be a BS of a WCDMA network in compliance with the WCDMA specification and other related specifications of the WCDMA technology and the receiver 110 may be a UE in compliance with the WCDMA specification and other related specifications of the WCDMA technology, but the invention is not limited thereto.

In this disclosure, novel HARQ retransmission schemes are provided for use in a data transmission management system 100 with at least one transmitter and one or more receivers based on a 2-dimensional (concatenated) coded system. The data transmission management system 100 also employs a HARQ technique. That is, when the receiver 110 receives a transmission from the transmitter 120, the receiver 110 may use the error detection bits to determine if data has been lost and then determine whether the data has been successfully detected according to the determination result. The receiver 110 may send feedback information with an acknowledgment (ACK) information to the transmitter 120 if the receiver 110 successfully receives and decodes the transmitted packet or send feedback information with a negative acknowledgment (NACK) information to the transmitter 120 if the receiver 110 fails to detect the transmitted packets. It is to be noted that the ACK or the NACK information may be represented by single bit or multiple bits.

The transmitter 120 is capable of encoding M uncoded packets into N coded packets with Q-packet error correction capability using a concatenated encoding scheme, wherein the M uncoded packets are first encoded by a first encoding scheme and then encoded into N coded packets by a second encoding scheme and where M≦N, and Q≧1. As aforementioned, the concatenated encoding method may comprise, for example, but not limited to, two encoding schemes: horizontal coding scheme (channel coding) and vertical coding scheme. Further, a vertical coding scheme could be performed before or after a channel coding. With the concatenated encoding scheme, the transmitter 120 may perform a transformation of original M packets to generate N transformed packets (where M≦N) and add error detection/correction bits (e.g. CRC) to each of the N transformed packets and encode the transformed N packets to obtain N coded packets.

In this disclosure, each receiver 110 may utilize a single ACK/NACK criterion or a multiple ACK/NACK criterion in one-transmission for feedback of the HARQ acknowledgement for indicating decoding status(es) of received packet(s) to the transmitter, according to predefined feedback criterion. Note that the transmitter 120 may sequentially transmit a set or all of N coded packets to one (single user case) or more receivers (multiple-user case) 110 and then receive at least one feedback information from one or more receivers 110, wherein the at least one feedback information comprises at least one ACK or NACK information for indicating decoding statuses of the transmitted coded packets and each of the transmitted coded packets has one of the decoding statuses corresponding thereto.

Each receiver 110 may send one feedback information with an ACK or a NACK information or a plurality of feedback information for the transmitted coded packets, according to a feedback criterion applied thereto, to the transmitter 120. For example, the feedback criterion applied to each receiver 110 at least comprises a single ACK/NACK criterion which indicates that each receiver 110 may send one feedback information with one ACK and/or NACK information for the transmitted packets and a multiple ACK/NACK criterion which indicates that each receiver 110 may send a plurality of feedback information, each of which with at least one ACK or NACK information, for the transmitted packets. If the single ACK/NACK criterion is applied, each receiver 110 may send one feedback information comprises an ACK or NACK information for indicating whether the M uncoded packets has been successfully decoded from each receiver 110. For example, each receiver 110 may send an ACK information with one or more bits to the transmitter 120 to indicate that the M uncoded packets has been successfully decoded or send a NACK information to the transmitter 120 to indicate that the M uncoded packets can not be successfully decoded after all of K (K≦N) transmitted packets have been received. If the multiple ACK/NACK criterion is applied, each receiver 110 may send multiple ACKs or NACKs information to the transmitter 120 for indicating the decoding statuses of a portion or all of the transmitted packets upon reception of a portion or all of the transmitted packets. For example, in one embodiment, each receiver 110 may immediately send an ACK or a NACK information for indicating the decoding status of each or a portion of transmitted packet upon reception of each or a portion of transmitted packet such that the transmitter 120 may sequentially receive a plurality of feedback information corresponding to the transmitted coded packets from each receivers 110 in response to a transmission order of the transmitted coded packets. The transmitter 120 may then determine whether to transmit a new packet or start a data retransmission procedure to retransmit a dedicated packet to one or more receivers 110 according to the number of the ACK information or NACK information collected in the feedback information from the one or more receivers 110. The dedicated packet may be a packet selected from any of N coded packets. Methods for data transmission management are described below.

When the receiver 110 does not successfully receive the data information and the number of retransmission is smaller than the pre-defined maximum retransmission number, the transmitter 120 will retransmit one or more dedicated packets. When receiving a retransmitted packet, each receiver 110 may combine the new packet with the old one (referred to as soft combining). Each receiver 110 may store the combined packet unless the detection is correct or the number of retransmission is equal to the maximum retransmission times. The coded bits may be further divided into several sub-bit-streams based on redundancy version selection. The transmitter 120 may sequentially receive the feedback information from one or more receivers 110, collect the number of ACK/NACK included in the feedback information and then determine whether to perform a retransmission procedure to retransmit a dedicated packet to one or more receivers 110 according to the number of collected ACK/NACK included in the feedback information. For example, in one embodiment, the receiver 110 may send one feedback information with an ACK or a NACK information immediately once receiving a transmitted coded packets from the transmitter 120 and the transmitter 120 may then perform the retransmission procedure at next transmission cycle if the feedback information comprises the NACK information. The retransmission procedure is performed or stopped when the number of collected ACK/NACK is equal to a specific value or a predetermined maximum number of retransmissions have been reached. Several embodiments of the method of data transmission management are provided below for more detail.

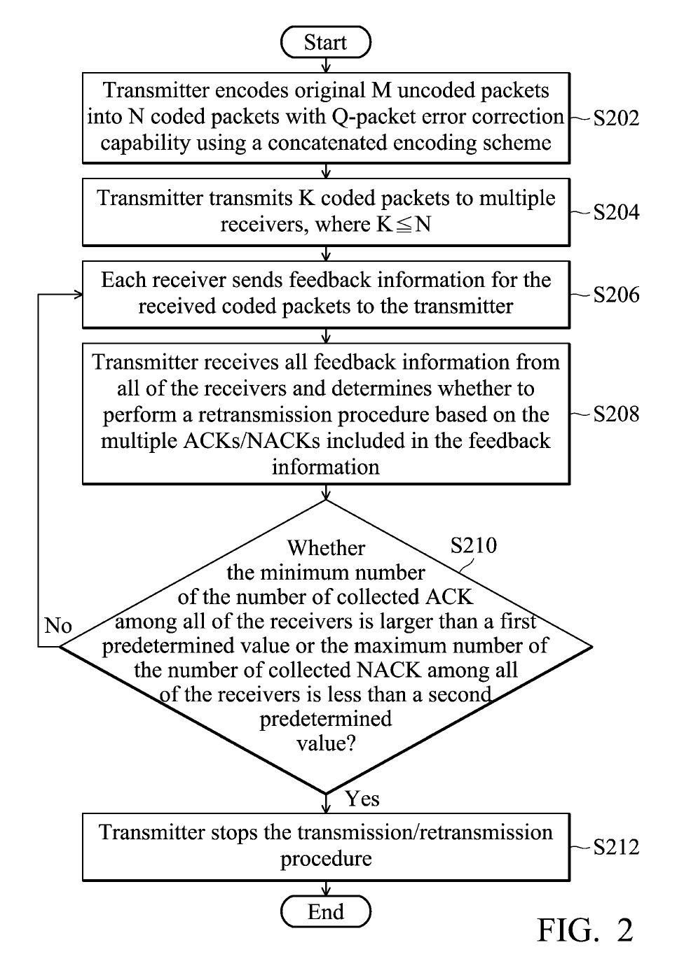

FIG. 2 is a schematic diagram illustrating a flowchart of a method for data transmission management used in multiple-user scenarios according to an embodiment of the disclosure. Please refer to FIGS. 1 and 2. The method for data transmission management of the disclosure can be applied in the data transmission management system 100 shown in FIG. 1 for managing data transmitted between a receiver and a transmitter. In this embodiment, assume that M transport blocks are to be encoded, N packets are to be transmitted, and error correct capability of the additional FEC decoder is Q-packet.

In step S202, the transmitter 120 encodes original M uncoded packets into N coded packets with Q-packet error correction capability using a concatenated encoding scheme. Thereafter, in step S204, the transmitter 120 transmits K coded packets to multiple receivers, where K≦N. For example, if 8 coded packets are generated (N=8), the transmitter 120 may transmit 6, 7 or 8 coded packets to all of the receivers 110.

In step S206, each receiver 110 may receive transmitted packets and sends feedback information for the received packets to the transmitter 120, wherein the feedback information including multiple ACKs/NACKs which indicates whether each or a portion of the transformed packets have been successfully decoded or not. In step S208, the transmitter 120 receives all feedback information from all of the receivers and determines whether to perform a retransmission procedure to retransmit a portion or all of the N coded packets to the receivers 110 based on the multiple ACKs/NACKs included in the feedback information. For example, but not limited to, each receiver 110 may send one feedback information with an ACK or a NACK information immediately once receiving a transmitted packet from the transmitter 120 and the transmitter 120 may then perform the retransmission procedure at next transmission cycle if the feedback information comprises the NACK information.

After receiving the retransmitted packets, in step S210, the transmitter 120 further determine whether the minimum number of the number of collected ACK among all of the receivers is larger than a first predetermined value (e.g. N−Q) or whether the maximum number of the number of collected NACK among all of the receivers is less than a second predetermined value. If the transmitter 120 determines that the minimum number of the number of collected ACK among all of the receivers is less than the first predetermined value or the maximum number of the number of collected NACK among all of the V receivers is larger than a second predetermined value (No in step S210), the receiver returns to steps S206-S208 to send another feedback information including multiple ACKs/NACKs which indicates whether each or a portion of the transformed packets have been successfully decoded or not to the transmitter 120 so that the transmitter 120 may receive all feedback information from all of the receivers and determine whether to retransmit a portion or all of the N coded packets to the receivers 110 based on the multiple ACKs/NACKs included in each report until the maximum number of retransmissions have been reached or all of the receivers have successfully decoded the N-Q packets. If the transmitter 120 determines that the minimum number of the number of collected ACK among all of the receivers is larger than the first predetermined value or the maximum number of the number of collected NACK among all of the V receivers is less than a second predetermined value, in step S212, the transmitter 120 stops the transmission/retransmission procedure.

It is to be noted that, in the multiple-user scenario, if some of the receivers among the receivers have successfully decoded N−Q packets in step S210, these receivers can stop receiving packets transmitted by the transmitter 120 and the transmitter 120 may only perform the retransmission procedure on remaining receivers which are not successfully decoded N−Q packets. For example, if there are four receivers A, B, C, D and the receivers A, B have successfully decoded N−Q packets, the transmitter 120 will perform the retransmission procedure based on the statuses (ACKs/NACKs) of remaining receivers C, D. Therefore, the time needed for retransmission can be further reduced.

In some embodiments, the transmitter 120 may further determine not to perform the retransmission procedure until all of the K coded packets have been transmitted to all of the receivers and then determine whether to perform the retransmission procedure to retransmit the dedicated packet selected from an intersection set of error packets of all of the V receivers when the intersection among the error packets of each of the receivers is not empty and the number of collected NACKs included in the feedback information for any of the receivers is larger than a predetermined value Q. When the intersection among the error packets of each of the receivers is empty, the transmitter 120 may further determine to perform the retransmission procedure to retransmit the dedicated packet selected from a union set of error packets of all of the receivers or from an un-transmitted set.

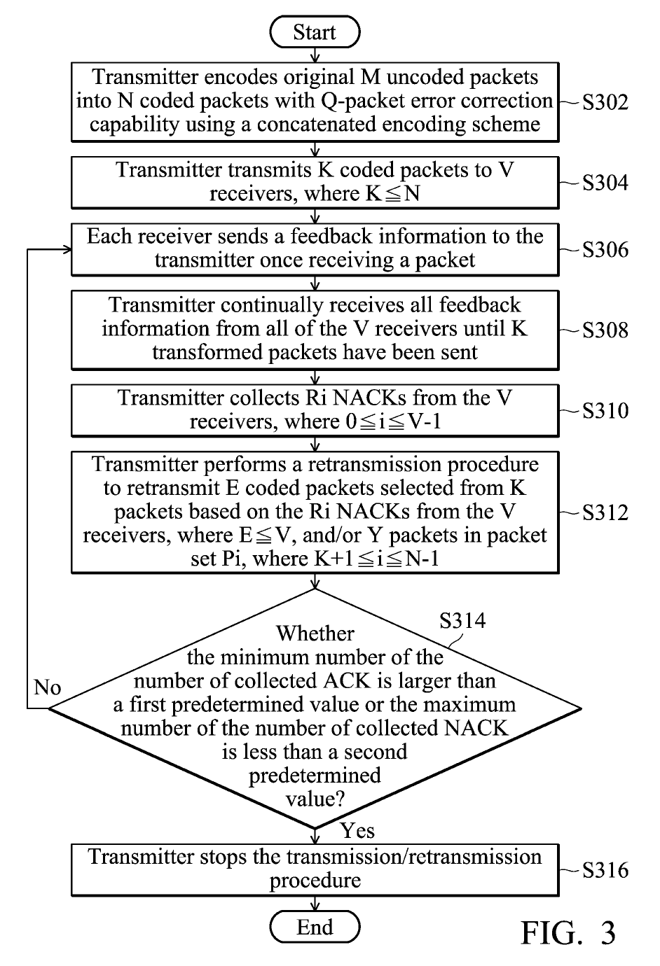

FIG. 3 is a schematic diagram illustrating a flowchart of a method for data transmission management used in multiple-user scenarios according to another embodiment of the disclosure. Please refer to FIGS. 1 and 3. In this embodiment, assume that M transport blocks are to be encoded, N packets are to be transmitted, error correct capability of the additional FEC decoder is Q-packet and V receivers are in the communication group.

In step S302, the transmitter 120 encodes original M uncoded packets into N coded packets with Q-packet error correction capability using a concatenated encoding scheme.

Thereafter, in step S304, the transmitter 120 transmits K coded packets selected from the N coded packets to V receivers, where K≦N. In step S306, each receiver 110 may send feedback information to the transmitter 120 once receiving a packet, wherein the feedback information includes one ACK or NACK which indicates whether the current transmitted packet has been successfully decoded or not. In this embodiment, the transmitter 120 does not perform the retransmission procedure immediately when receiving an ACK/NACK information from each receiver. In step S308, the transmitter 120 continually receives all feedback information from all of the V receivers until K transformed packets have been sent. After the K transformed packets have been sent, in step S310, the transmitter 120 collects R, NACKs from the V receivers, where 0≦i≦V−1. Then, in step S312, the transmitter 120 performs a retransmission procedure to retransmit E coded packets selected from K packets based on the R, NACKs from the V receivers, where E≦V, and/or Y packets in packet set Pᵢ, where K+1≦i≦N−1. After receiving the retransmitted packets, in step S314, the transmitter 120 further determines whether the minimum number of the number of collected ACK among all of the V receivers is larger than a first predetermined value (e.g. N−Q) or whether the maximum number of the number of collected NACK among all of the at least one receiver is less than a second predetermined value. If the transmitter 120 determines that the minimum number of the number of collected ACK among all of the V receivers is less than the first predetermined value or the maximum number of the number of collected NACK among all of the V receivers is larger than a second predetermined value (No in step S314), each receiver returns to step S306 to continually send another feedback information including single ACK/NACK which indicates whether the retransmitted packet has been successfully decoded or not to the transmitter 120 so that the transmitter 120 may receive all feedback information from all of the receivers and determine whether to retransmit a portion or all of the N coded packets to the receivers 110 based on the R, NACKs from the V receivers until the maximum number of retransmissions have been reached or all of the receivers have successfully decoded the N−Q packets. If the transmitter 120 determines that the minimum number of the number of collected ACK among all of the V receivers is larger than the first predetermined value or the maximum number of the number of collected NACK among all of the V receivers is less than a second predetermined value, in step S316, the transmitter 120 stops the transmission procedure.

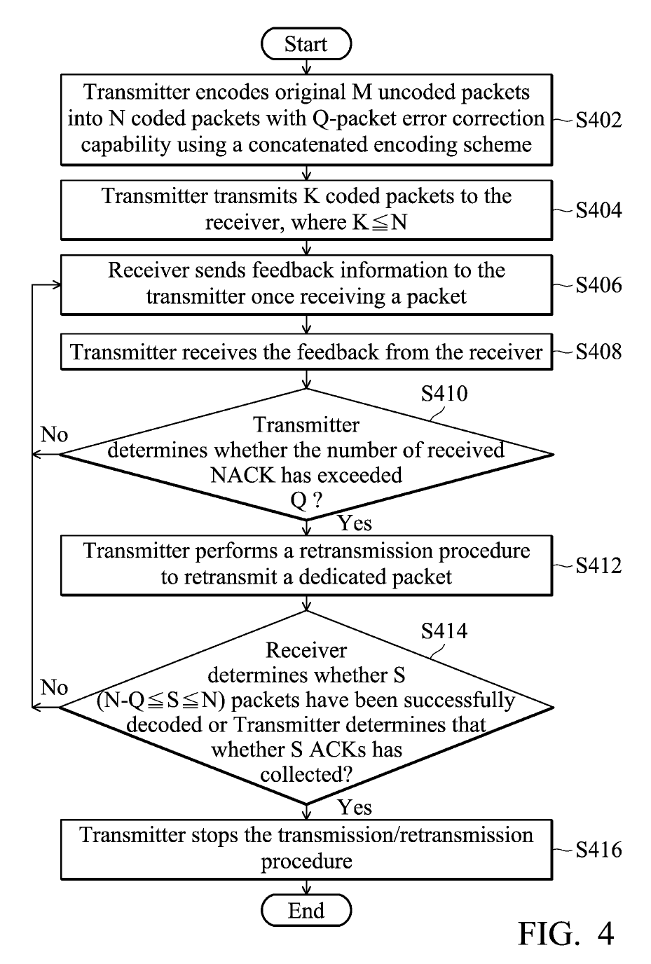

FIG. 4 is a schematic diagram illustrating a flowchart of a method for data transmission management used in single user scenarios according to yet another embodiment of the disclosure. Please refer to FIGS. 1 and 4. In this embodiment, assume that M transport blocks are to be encoded, N packets are to be transmitted, and error correct capability of the additional FEC decoder is Q-packet.

In step S402, the transmitter 120 encodes original M uncoded packets into N coded packets with Q-packet error correction capability using a concatenated encoding scheme.

Thereafter, in step S404, the transmitter 120 transmits K coded packets to the receiver 110, where K≦N. In step S406, the receiver 110 may send feedback information to the transmitter 120 once receiving a packet, wherein the feedback information includes single ACK/NACK which indicates whether the transformed packet is successfully decoded or not. In step S408, the transmitter 120 receives the feedback from the receiver 110 and determines whether the number of received NACK has exceeded Q (step S410). If not, which means no retransmission is needed, the transmitter 120 continually receives subsequent feedback information from the receiver 110 until the number of collected NACK has exceeded Q. When determining that the number of collected NACK has exceeded Q (Yes in step S410), in step S412, the transmitter 120 may perform a retransmission procedure to retransmit a dedicated packet which is the same as the basic HARQ transmission. After receiving the retransmitted packets, in step S414, the receiver 110 further determines whether S (N−Q≦S≦N) packets have been successfully decoded or the transmitter 120 determines whether S ACKs have been collected. When the receiver 110 detects S successfully decoded packets, it stops receiving any packet from the transmitter 120. Similarly, when the transmitter 120 has collected S ACKs, it stops transmitting any packet to the receiver 110.

For explanation, specific embodiments are illustrated in the following to explain the detailed process of a method for data transmission management of the disclosure, and those skilled in the art will understand that the specific embodiments are used for explanation only and the disclosure is not limited thereto. In the embodiments, assume that M transport blocks are to be encoded, N packets are to be transmitted, and error correct capability of the additional FEC decoder is Q-packet. For illustration purposes, the transmitter 120 is assumed to be a BS transmitter, and the receiver 110 is assumed to be a UE receiver. Specifically, assume that there are 6 (M=6) transport blocks to be encoded, 8 (M=8) packets left after concatenated encoding, and error correct capability of the additional FEC decoder is 2-packet (Q=2).

In some embodiments, when the transmitter 120 transmits N packets for first transmission and the single ACK/NACK criterion is utilized for each transmitted packet at the receiver 110 side for feedback of the HARQ acknowledgement to report detection status of received packet(s), the transmitter 120 may either sequentially transmit the N packets at each available opportunity or start retransmission when more than Q NACKs has been received and all of the N packets have been sent out.

Note that in the following, the un-decoded packets are the set of “un-decoded packets” including failed decoded packets and un-transmitted packets, wherein failure decoded packets or error packets are packets transmitted by the BS, but not detected by the UE, and un-transmitted packets are packets which are not transmitted by the BS.

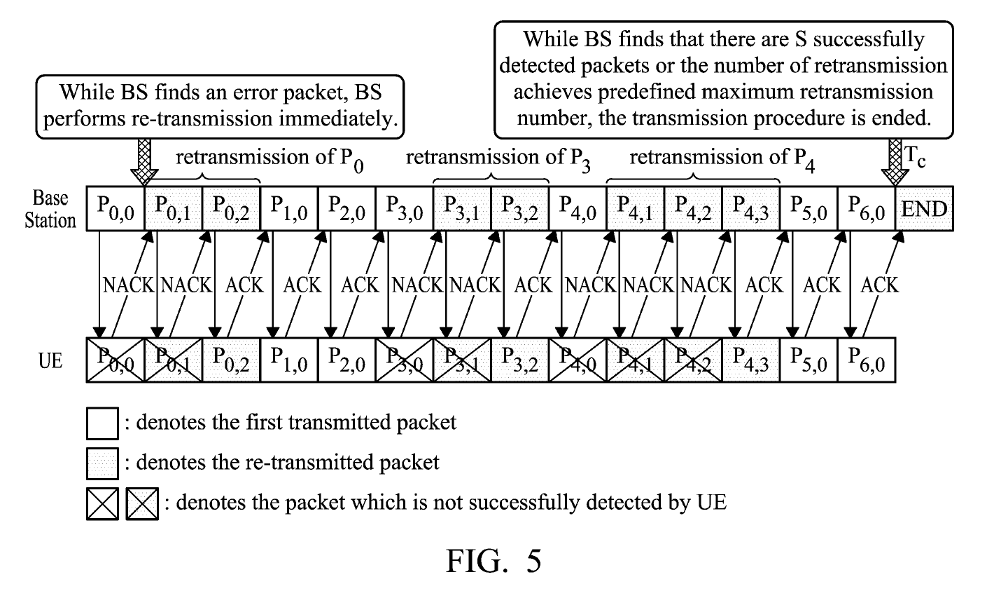

In one embodiment, the UE feedback criterion is defined as reporting a ACK/NACK information immediately once the UE receives a packet. The BS transmission/retransmission criterion is defined as having occurred once the BS detects an NACK on the packet P_{i,j} (where P_{i,j}: denotes the i^{th} packet from j^{th} redundancy version; i denotes the i^{th} packet; and j denotes redundancy version index). In this case, the BS retransmits the error packet P_{i,j+1} immediately. This retransmission procedure will be ended when the BS detects an ACK or achieves a maximum number of retransmission. If the BS detects an ACK on the i^{th} packet, the BS will transmit the new packet P_{i+1,0} to the UE. The BS stop criterion is defined as having occurred when the BS stops the retransmission procedure once the BS receives a specific number S of ACKs (N−Q≦S≦N) or achieves a maximum number of retransmission. For example, the specific number S may equal to N or M. The UE stop criterion is defined as having occurred when the UE stops receiving the packet UE successfully detects S packets, or achieves a maximum number of retransmission. For example, please refer to FIG. 5. As shown in FIG. 5, there are 6 transport blocks to be encoded, 8 packets left after concatenated encoding, and error correct capability of the additional FEC decoder is 2-packet. The maximum number of successfully received packets (S) is 7. The maximum number of retransmission is four. When the BS receives NACK information on the packets {P_{0,0}, P_{0,1}, P_{3,0}, P_{3,1}, P_{4,0}, P_{4,1}, P_{4,2}}, the BS retransmits the current error packet to the UE immediately. When the BS receives the ACK information on the packets {P_{0,2}, P_{1,0}, P_{2,0}, P_{3,2}, P_{4,3}, P_{5,0}}, the BS transmits a new packet to the UE immediately. When the BS receives ACK information on the packets P_{6,0}, the BS stops the transmission procedure because the BS already would have received 7 ACKs.

In some embodiments, the BS will not be retransmitted immediately when receiving any ACK/NACK information. Until the BS sends K first transmitted packets, the BS may receive the plurality of feedback information, each with an ACK or a NACK information, for all of the transmitted packets, when the feedback criterion applied to the UE is a multiple ACK/NACK criterion, and the BS may further determine to perform the retransmission procedure to retransmit the dedicated packet to the UE until all of the K coded packets have been transmitted and the number of collected NACKs included in the feedback information is larger than Q. In this case, the dedicated packet may be a packet selected from the set of un-decoded packets, if the number of collected NACKs is larger than Q, wherein the un-decoded packets includes the error packets which are the packets being transmitted to and not being detected by the UE and un-transmitted packets which are the packets are not being transmitted by the BS.

In some embodiments, the dedicated packet is a packet selected from the set of error packets, if the number of collected NACKs is larger than Q; otherwise, the BS may transmit a first packet which is a packet selected from the set of un-decoded packets.

In some embodiments, when the BS transmits N packets for a first transmission and the single ACK/NACK criterion is utilized for all N transmitted packets at the UE side for feedback of the HARQ acknowledgement to report decoding status of received packet(s), it may either sequentially transmit the N packets at each available opportunity or start retransmission when any NACK is received and portion or all of the N packets have been sent out.

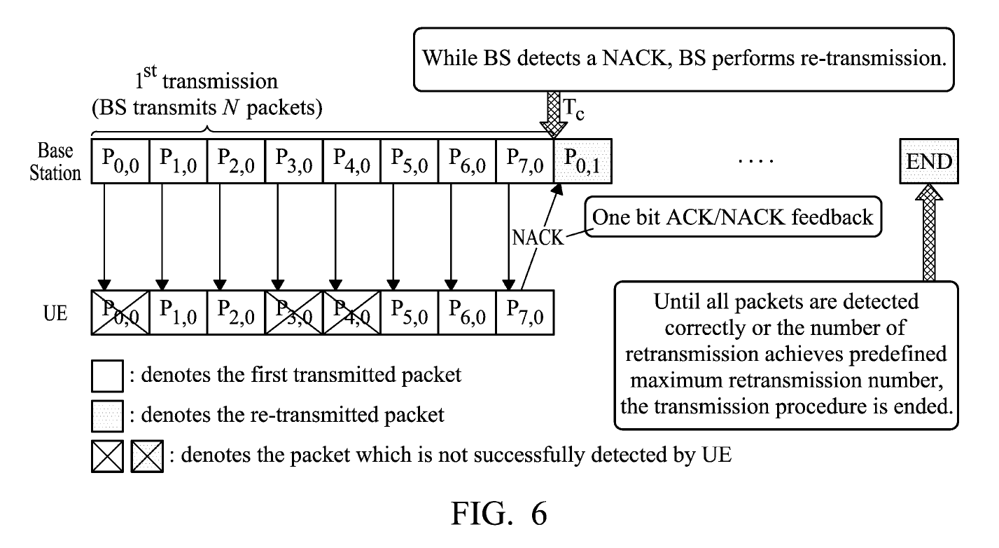

In some embodiments, the BS may receive one feedback information with an ACK or a NACK information for a portion or all of the transmitted packets, when the feedback criterion applied to the at least one UE is a single ACK/NACK criterion, and the BS may determine to perform the retransmission procedure to retransmit the dedicated packet to the at least one UE, when the number of collected NACKs included in the feedback information is 1. Refer to FIG. 6. In the example of FIG. 6, the UE feedback criterion is defined as having occurred when the UE does not report ACK/NACK information immediately. The UE reports one bit ACK/NACK information when receiving N packets. If the number of successfully detected packets is less than N−Q, the UE reports the NACK. Otherwise, the UE reports the ACK information if the number of successfully detected packets is larger than or equal to N−Q. The BS transmission/retransmission criterion is defined as having occurred when the BS transmits N first transmitted packets {P_{0,0}, P_{1,0}, P_{2,0}, . . . , P_{N-1,0}} to the UE, the BS retransmits packets from the set of “transmitted packets” when detecting NACK information. This retransmission procedure will be ended when the BS detects an ACK or achieves a maximum number of retransmission. Once the BS receives an ACK, or achieves a maximum number of retransmission, the BS stops transmission/retransmission. If the UE successfully detects N−Q packets, or achieves a maximum number of retransmission, the UE stops receiving packets. As shown in FIG. 6, the number of first transmitted packets (N) is 8, and the maximum number of retransmission is four. The BS receives NACK information on the transmitted packets {P_{0,0}, P_{1,0}, P_{2,0}, P_{3,0}, P_{4,0}, P_{5,0}, P_{6,0}, P_{7,0}}. The BS retransmits a packet from the set of “transmitted packets” until the BS transmitted 8 packets {P_{0,0}, P_{1,0}, P_{2,0}, P_{3,0}, P_{4,0}, P_{5,0} P_{6,0}, P_{7,0}} to the UE. At the checking time T_{c}, the set of transmitted packets is {P₀, P₁, P₂, P₃, P₄, P₅, P₆, P₇}, the set of successfully decoded packets is {P₁, P₂, P₅, P₆, P₇}, and the set of failure decoded packets is {P₀, P₃, P₄}. Therefore, the BS retransmits the packet P_{0,1}.

In some embodiments, the BS may receive the plurality of feedback information, each with an ACK or a NACK information, for all of the transmitted packets, when the feedback criterion applied to the UE is a multiple ACK/NACK criterion and determines not to perform the retransmission procedure until all of the K coded packets have been transmitted, and determines to perform the retransmission procedure to retransmit the dedicated packet selected from the set of error packets, when the number of collected NACKs included in the feedback information is larger than Q or to perform a transmission procedure to transmit a packet selected from the set of un-decoded packets to the UE when the number of collected NACKs included in the feedback information is less than or equal to Q. In this embodiment, the UE does not report ACK/NACK information immediately. UE reports multiple ACK/NACK information for the received packets. In this scenario, the UE could report a detection status of all or a portion of the received packets. Until the BS transmits K first transmitted packets {P_{0,0}, P_{1,0}, P_{2,0}, . . . , P_{K-1,0}} to the UE, the BS retransmits one or a portion of packets from the set of “failure detected packets” or one or a portion of packets from the set of “un-decoded packets” when the number of detects NACKs is larger than Q. This retransmission procedure will be ended when the BS detects predetermined number of ACKs or achieves a maximum number of retransmission. For example, assume that the number of first transmitted packets (K) is 6 and the maximum number of retransmission is four. In this example, the UE reports a detection status of all received packets. The BS may receive NACK information on the packets {P_{0,0}, P_{3,0}, P_{4,0}}, and the number of error packets is larger than 2. Therefore, the BS may retransmit a packet from the set of “failure decoded packets” {P₀, P₃, P₄}, until the BS transmits 6 packets {P_{0,0}, P_{1,0}, P_{2,0}, P_{3,0}, P_{4,0}, P_{5,0}} to the UE.

In one embodiment, the UE reports the ACK/NACK information immediately once receiving a packet and the BS retransmits a packet from the set of “failure detected packets” when the number of NACKs is larger than Q. Otherwise, the BS transmits a packet from the set of “un-decoded packets”. The BS may stop transmission once the BS receives S (N−Q≦S≦n) ACKs, or achieves a maximum number of retransmission. The UE may stop receiving packets UE successfully detects S (N−Q≦S≦n) packets, or achieves a maximum number of retransmission.

In the following, several exemplary embodiments of a HARQ feedback scheduling method in multiple-user scenarios are disclosed. Similarly, the concatenated coding scheme is applied and it is assumed that M transport blocks are to be encoded and after performing a concatenated coding scheme, N packets are generated after concatenated encoding. In the following embodiments, error correct capability of the additional forward-error-correction (FEC) scheme is assumed to be Q packets. In other words, the additional error decoder can correctly detect when the number of error packets is less than or equal to Q. Therefore, the error packets can be decoded correctly when receiving N−Q successfully decoded packet. On the contrary, at least one dedicated packet has to be retransmitted from the transmitter to the receiver when the number of error packets is larger than Q.

In the embodiments, assume that there are M transport blocks to be encoded, N packets to be transmitted, error correct capability of the additional FEC decoder is Q-packet, and there are V users in the communication group. The transmitter is assumed to be a BS, and the receiver is assumed to be a UE. Specifically, assume that there are 6 transport blocks to be encoded, 8 packets left after concatenated encoding, error correct capability of the additional FEC decoder is 2-packet, and the number of users in this communication group is 2.

In some embodiments, the feedback information includes a plurality of bits for all of the transmitted packets when the feedback criterion applied to each of the V receivers is a multiple ACK/NACK criterion and the BS may receive the plurality of feedback information, each with an ACK or a NACK information, for all of the transmitted packets from each of the V receivers and then determines to perform the retransmission procedure to retransmit the dedicated packet when the number of collected NACK information from one of the V receivers included in the feedback information is larger than a first predetermined value. The BS may stop the transmission of packets to V receivers when the minimum number of the number of collected ACK among all of the V receivers is larger than the first predetermined value or when the maximum number of the number of collected NACK among all of the V receivers is less than a second predetermined value or when a predetermined maximum number of retransmissions have been reached.

In some embodiments, the BS may sequentially receive a plurality of feedback information corresponding to the transmitted coded packets from the V receivers in response to a transmission order of the transmitted coded packets and then determine whether to perform the retransmission procedure to retransmit the dedicated packet to the V receivers according to collected ACK or NACK information included in the previously received feedback information before the set or all of the N coded packets have been transmitted.

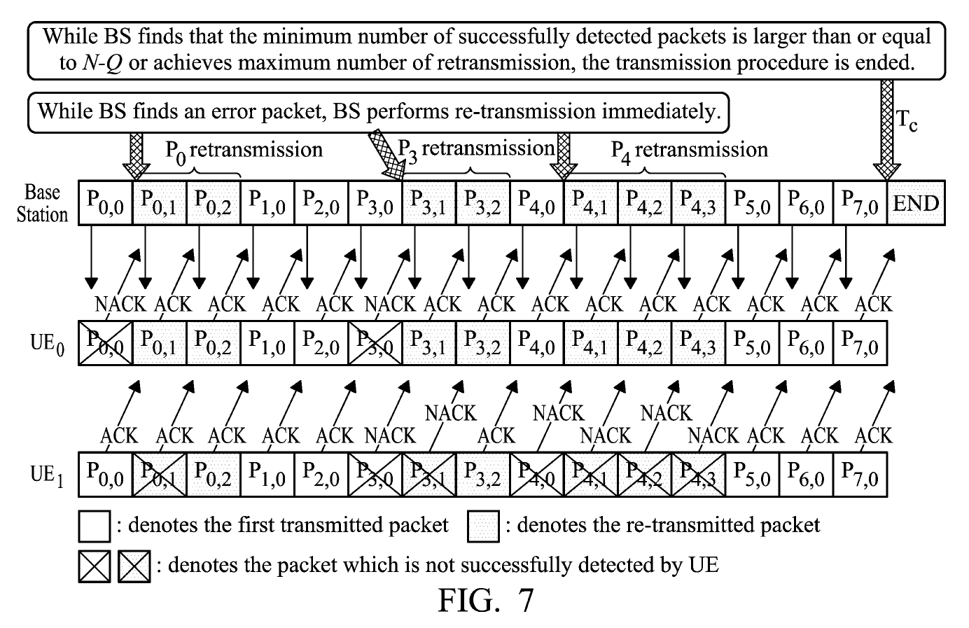

In some embodiments, the BS may receive the plurality of feedback information, each with an ACK or a NACK information, for all of the transmitted packets from each of the V receivers when the feedback criterion applied to the V receivers is a multiple ACK/NACK criterion, and determine whether to perform the retransmission procedure to retransmit the dedicated packet to the V receivers, when the number of collected NACKs included in the feedback information for any of the V receivers is 1. In one embodiment, the UE feedback criterion is defined as having occurred when the UE reports the ACK/NACK information immediately once UE receives a packet. The BS transmission/retransmission criterion is defined as having occurred when the BS detects NACK information on the packet P_{i,j} of any UEs (where P_{i,j}: denotes the i^{th} packet from j^{th} redundancy version; i denotes the i^{th} packet; and j denotes redundancy version index), and the BS retransmits the error packet P_{i,j+1} immediately. This retransmission procedure will be ended when the BS detects ACK information from all UEs or achieves a predetermined maximum number of retransmission. If the BS detects ACK information from all UEs on i^{th} packet, the BS transmits the new packet P_{i+1,0} to the UEs. The BS stop criterion is defined as having occurred once the BS receives ACK information from all UEs on the packet P_{N-1}, or achieves a maximum number of retransmission. The UE stop criterion is defined as having occurred when the UE successfully detects N packets, or achieves a maximum number of retransmission. For example, as shown in FIG. 7, the maximum number of retransmission is four. The UE₀ fails to detect the packets {P_{0,0}, P_{3,0}}, and the UE₁ fails to detect the packets {P_{0,1}, P_{3,0}, P_{3,1}, P_{4,0}, P_{4,1}, P_{4,2}}. When the BS receives NACK information on the packets {P_{0,0}, P_{3,0}, P_{3,1}, P_{4,0}, P_{4,1}, P_{4,2}}, the BS retransmits the current error packet to the UEs immediately. When the BS receives the ACK information on the packets {P_{0,2}, P_{1,0}, P_{2,0}, P_{3,2}, P_{5,0}, P_{6,0}}, the BS transmits a new packet to the UE immediately. When the BS receives a NACK information on the packets P_{4,3}, the BS transmits packets P_{5,0} to the UE because the retransmission times achieved a maximum number. When the BS receives ACK information on the packets P_{7,0}, the BS stops the transmission procedure.

It is to be noted that, as shown in the example of FIG. 7, the UE₁ replies an ACK information on the packet P_{0,1} to the BS even if it fails to detect the packet P_{0,1} because it has successfully detected the packet P_{0,0} previously. In another embodiment, the UE₁ may determine not to receive or reply any ACK/NACK information on the packet P_{0,1} so that the BS does not need to retransmit another redundancy version of the packet P₀ (e.g. the packets P_{0,2}) to the UE₁.

In some embodiments, if for UEᵢ the number of failure detected packets is Wᵢ, and the number of successfully detected packets is Zᵢ (0≦i≦V−1), then the BS will collect ACK/NACK information from V users. In this embodiment, the BS transmission/retransmission criterion is defined as having occurred when the BS detects NACK information on the packet P_{i,j} from any UE (where P_{i,j}: denotes the i^{th} packet from j^{th} redundancy version; i denotes the i^{th} packet; and j denotes redundancy version index), and the BS retransmits error packet P_{i,j+1} immediately. This retransmission procedure will be ended when the BS detects ACK information from all UEs or achieves a maximum number of retransmission. If the BS detects ACK information from all UEs on i^{th} packet, the BS will transmit the new packet P_{i+1,0} to the UEs.

The BS stop criterion is defined as having occurred when the minimum number of successfully detected packets is larger than or equal to N−Q, min(Z₀, Z₁, . . . , Z_{V-1})≧N−Q, or a maximum number of retransmission is achieved. The UE feedback criterion is defined as having occurred when the UE receives a packet, and the UE reports the ACK/NACK information immediately. The UE stop criterion is defined as having occurred when the UE successfully detects N−Q packets, or achieves a maximum number of retransmission.

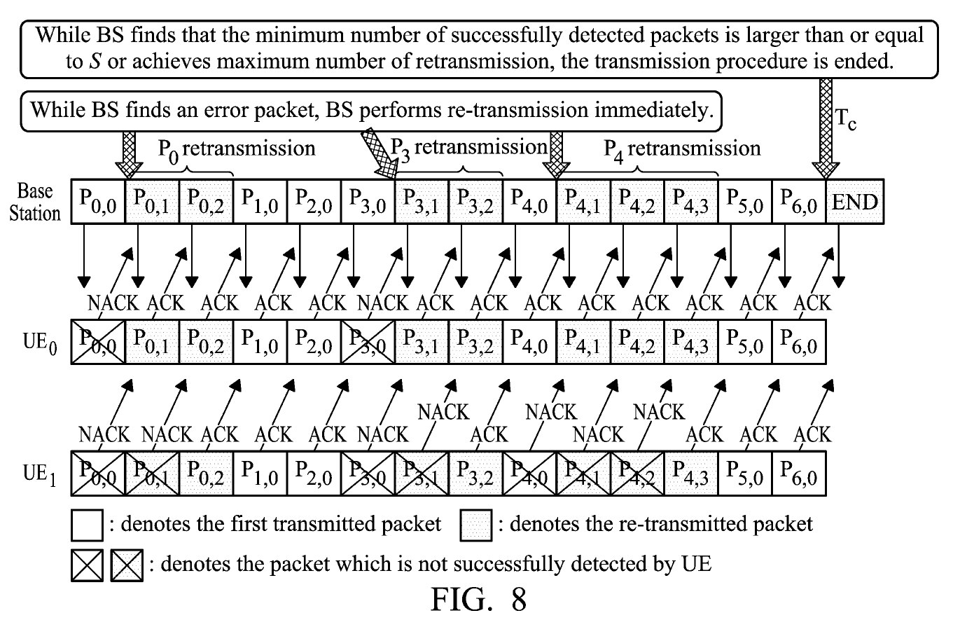

In another embodiment, the BS will collect ACK/NACK information from V users. The UE feedback criterion is defined as having occurred when the UE receives a packet, such that the UE reports the ACK/NACK information immediately. The BS transmission/retransmission criterion is defined as having occurred when the BS detects NACK information on the packet P_{i,j} from any UEs (where P_{i,j}: denotes the i^{th} packet from j^{th} redundancy version; i denotes the i^{th} packet; and j denotes redundancy version index), and the BS retransmits error packet P_{i,j+1} immediately. This retransmission procedure will be ended when the BS detects ACK information from all UEs or achieves a maximum number of retransmission. If the BS detects ACK information from all UEs on i^{th} packet, the BS transmits the new packet P_{i+1,0} to the UEs. The BS stop criterion is defined as having occurred when the minimum number of successfully detected packets is larger than or equal to S (N−Q≦S≦N), min(Z₀, Z₁, . . . , Z_{V-1})≧S, or a maximum number of retransmission is achieved. The UE stop criterion is defined as having occurred when the UE successfully detects S (N−Q≦S≦N) packets, or achieves a maximum number of retransmission. For example, as shown in FIG. 8, the maximum number of successfully received packets (S) is 7, and the maximum number of retransmission is four. The UE₀ fails to detect the packets {P_{0,0}, P_{3,0}}, and the UE₁ fails to detect the packets {P_{0,0}, P_{0,1}, P_{3,0}, P_{3,1}, P_{4,0}, P_{4,1}, P_{4,2}}. When the BS receives NACK information on the packets P_{0,0}, P_{0,1}, P_{3,0}, P_{3,1}, P_{4,0}, P_{4,1}, P_{4,2}, the BS retransmits the current error packet to the UE immediately. When the BS receives the ACK information on the packets P_{0,2}, P_{1,0}, P_{2,0}, P_{3,2}, P_{4,3}, P_{5,0}, the BS transmits a new packet to the UE immediately. When the BS receives the ACK information on the packets P_{6,0}, the transmission procedure is ended because there are 7 successfully detected packets.

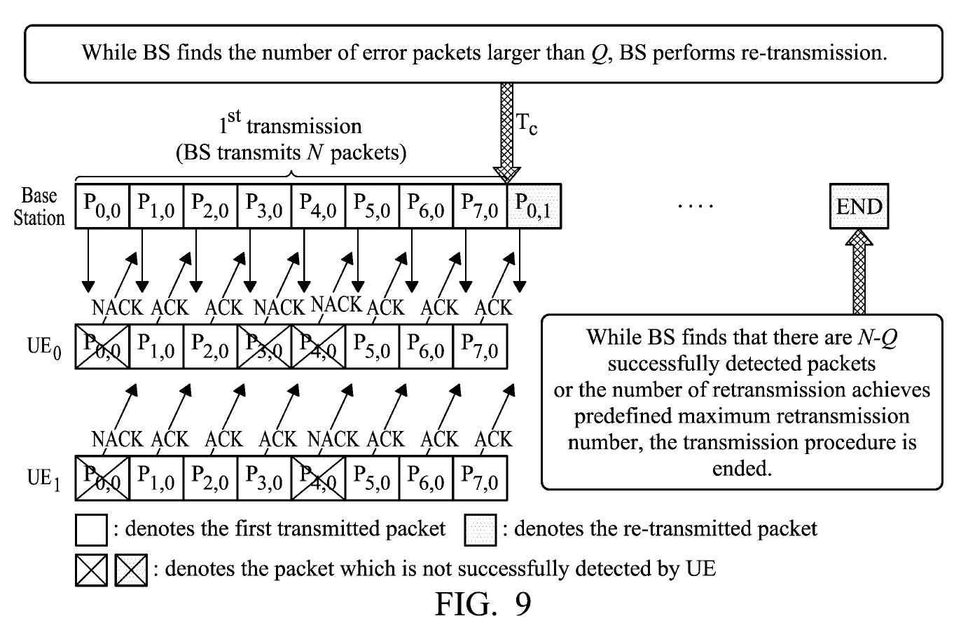

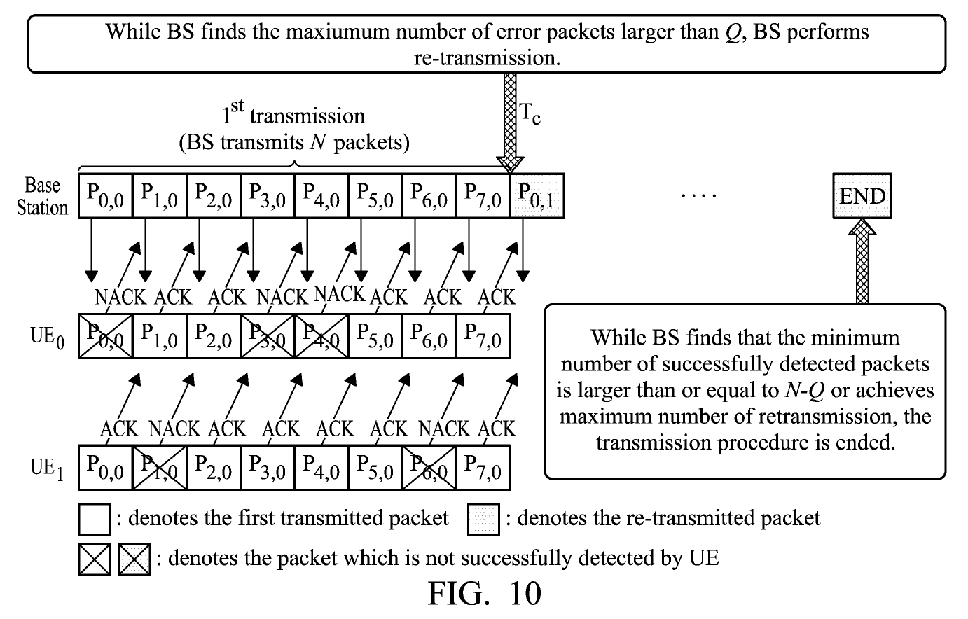

In one embodiment, UE receives a packet, the UE reports the ACK/NACK information immediately and the BS will not be retransmitted immediately when receiving ACK/NACK information. When the BS sends N first transmitted packets {P_{0,0}, P_{1,0}, P_{2,0}, . . . , P_{N-1,0}} to the UE, the BS retransmits a packet, if the number of error packets is larger than Q. The set of failure decoded packets from the UEₖ is denoted by ErrorSetₖ (0≦k≦V−1). If the intersection of each of the UE's failure decoded packets is joint (ErrorSet₀∩ErrorSet₁∩ . . . ∩ErrorSet_{V-1}≠Ø), the BS will retransmit the packet from the intersection set, wherein the intersection of the two sets A and B is the collection of points which are in both A and B. A∩B={x: xεA and xεB}. Otherwise, if the intersection of each of the UE's failure decoded packets is disjointed (ErrorSet₀∩ErrorSet₁∩ . . . ∩ErrorSet_{V-1}≠Ø), the BS will retransmit the packet from the union set (ErrorSet₀∪ErrorSet₁∪ . . . ∪ErrorSet_{V-1}), wherein the union of the two sets A and B is the collection of points which are in A or in B (or in both). A∪B={x: xεA or xεB}. This retransmission procedure will be ended when the BS detects ACK information from all UEs or achieves a maximum number of retransmission. The BS stop criterion is defined as having occurred when the minimum number of successfully detected packets is larger than or equal to N−Q, min(Z₀, Z₁, . . . , Z_{V-1}) N−Q, or achieves a maximum number of retransmission. The UE stop criterion is defined as having occurred when the UE successfully detects N−Q packets, or achieves a maximum number of retransmission. For example, refer to FIGS. 9 and 10, where the UE₀ and UE₁ have the same error packet as in FIG. 9 and where the UE₀ and UE₁ do not have the same error packet as in FIG. 10. As shown in FIG. 9, the maximum number of retransmission is four. The UE₀ failed to detect the packets {P_{0,0}, P_{3,0}, P_{4,0}}, and the UE₁ failed to detect the packets {P_{0,0}, P_{4,0}}. Therefore, the BS receives NACK information on the packets {P_{0,0}, P_{3,0}, P_{4,0}}, and the number of error packets is larger than 2. Because the intersection of each of the UE's failure decoded packets is jointed (ErrorSet₀∩ErrorSet₁≠Ø), the BS retransmits packets from the intersection set (ErrorSet₀∩ErrorSet₁={P_{0,0}, P_{4,0}}) to the UE. The BS retransmits a packet until the BS transmits 8 packets {P_{0,0}, P_{1,0}, P_{2,0}, P_{3,0}, P_{4,0}, P_{5,0}, P_{6,0}, P_{7,0}} to the UE. At the checking time T_{c}, the set of transmitted packets is {P₀, P₁, P₂, P₃, P₄, P₅, P₆, P₇}, the set of successfully decoded packets is {P₁, P₂, P₅, P₆, P₇}, the set of un-decoded packets of the UE₀ is {P₀, P₃, P₄}, and the set of un-decoded packets of the UE₁ is {P₀, P₄}

FIG. 10 is another example on above embodiment where the UE₀ and UE₁ do not have the same error packet. The maximum number of retransmission is four. UE₀ fails to detect the packets {P_{0,0}, P_{3,0}, P_{4,0}}, and UE₁ fails to detect the packets {P_{1,0}, P_{6,0}}. Therefore, the BS receives NACK information on the packets {P_{0,0}, P_{1,0}, P_{3,0}, P_{4,0}, P_{6,0}}, and the number of error packets is larger than 2. Because the intersection of each of the UE's failure decoded packets is disjointed (ErrorSet₀∩ErrorSet₁=Ø), the BS retransmits packets from the union set (ErrorSet₀∪ErrorSet₁={P_{0,0}, P_{1,0}, P_{3,0}, P_{4,0}, P_{6,0}}). The BS retransmits a packet until the BS transmits 8 packets {P_{0,0}, P_{1,0}, P_{2,0}, P_{3,0}, P_{4,0}, P_{5,0}, P_{6,0}, P_{7,0}} to the UE. At the checking time T_{c}, the set of transmitted packets is {P₀, P₁, P₂, P₃, P₄, P₅, P₆, P₇}, the set of successfully decoded packets is {P₂, P₅, P₇}, the set of un-decoded packets of the UE₀ is {P₀, P₃, P₄}, and the set of un-decoded packets of the UE₁ is {P₁, P₆}.

In some embodiments, when the UE receives a packet, the UE reports the ACK/NACK information immediately. The BS will not be retransmitted immediately when receiving ACK/NACK information. When the BS transmits K first transmitted packets {P_{0,0}, P_{1,0}, P_{2,0}, . . . , P_{K-1,0}} to the UEs, the BS retransmits a packet, if the number of error packets is larger than Q. The set of failure decoded packets from the UEₖ is denoted by ErrorSetₖ (0≦k≦V−1). If the intersection of each of the UE's failure decoded packets is jointed (ErrorSet₀∩ErrorSet₁∩ . . . ∩ErrorSet_{V-1}≠Ø), the BS will retransmit the packet from the intersection set. Otherwise, if the intersection of each of the UE's failure decoded packets is disjointed (ErrorSet₀∩ErrorSet₁∩ . . . ∩ErrorSet_{V-1}=Ø), the BS will retransmit the packet from the “un-transmitted set” when the number of un-transmitted packets is larger than zero, and the BS will retransmit the packet from the union set (ErrorSetₒ U ErrorSet₁∪ . . . ∪ErrorSet_{V-1}) when the number of un-transmitted packets is zero. This retransmission procedure will be ended when the BS detects ACK information from all UEs or achieves a maximum number of retransmission.

In some embodiments, the UE does not report ACK/NACK information immediately. The UE reports multiple ACK/NACK information for the received packets and when the BS transmits K first transmitted packets {P_{0,0}, P_{1,0}, P_{2,0}, . . . P_{K-1,0}} to the UE, the BS retransmits a packet when the maximum number of failure detected packets is larger than Q, max(W₀, W₁, . . . , W_{N-1})>Q. The set of failure decoded packets from the UEₖ is denoted by ErrorSetₖ (0≦k≦V−1). If the intersection of each of the UE's failure decoded packets is jointed (ErrorSet₀∩ErrorSet₁∩ . . . ∩ErrorSet_{V-1}≠Ø), the BS will retransmit the packet from the intersection set. Otherwise, if the intersection of each of the UE's failure decoded packets is disjointed (ErrorSet₀∩ErrorSet₁∩ . . . ∩ErrorSet_{V-1}=Ø), the BS will retransmit packets from the “un-transmitted set” when the number of un-transmitted packets is larger than zero, and the BS will retransmit packets from the union set (ErrorSet₀∪ErrorSet₁∪ . . . ∪ErrorSet_{V-1}) when the number of un-transmitted packets is zero. This retransmission procedure will be ended when the BS detects ACK information from all UEs or achieves a maximum number of retransmission.

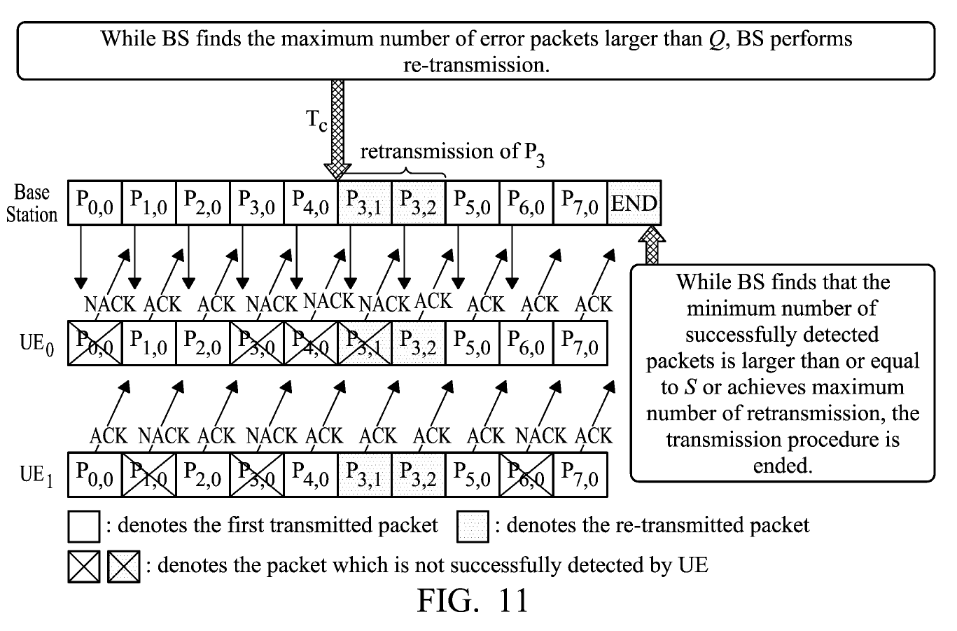

In some embodiments, when the UE receives a packet, the UE may report the ACK/NACK information immediately. The BS retransmits a packet from the set of “failure detected packets” when the maximum number of failure detected packets is larger than Q, max(W₀, W₁, . . . , W_{N-1})>Q. The set of failure decoded packets from the UEₖ is denoted by ErrorSetₖ (0≦k≦V−1). If the intersection of each of the UE's failure decoded packets is jointed (ErrorSet₀∩ErrorSet₁∩ . . . ∩ErrorSet_{V-1}≠Ø), the BS will retransmit the packet from the intersection set. Otherwise, the BS transmits a packet from the set of “un-decoded packets”. This retransmission procedure will be ended when the BS detects ACK information from all UEs or achieves a maximum number of retransmission. For example, refer to FIG. 11. As shown in FIG. 11, the maximum number of retransmission is four, and the maximum number of received packets (S) is 6. At the checking time T_{c}, the set of transmitted packets is {P₀, P₁, P₂, P₃, P₄}, the set of un-transmitted packets is {P₅, P₆, P₇}, the set of failure decoded packets of the UE₀ is {P₀, P₃, P₄}, and the set of failure decoded packets of the UE₁ is {P₀, P₃}. At time T_{c}, the maximum number of failure decoded packets is larger than 2. Therefore, the BS performs retransmission. Because the intersection of each of the UE's failure decoded packets is jointed (ErrorSet₀∩ErrorSet₁≠Ø), the BS retransmits packets from the intersection set (ErrorSet₀∩ErrorSet₁={P₃}). After the UE₀ and UE₁ successfully detects the packet P_{7,0}, the set of failure decoded packets of the UE₀ is {P₀, P₄}, and the set of failure decoded packets of the UE₁ is {P₀, P₆}. In other words, the minimum number of successfully detected packets is equal to 6. Therefore, the transmission procedure is ended after the UE₀ and UE₁ successfully detects the packet P_{7,0}.

In summary, according to the data transmission management systems and methods for data transmission management in the transmitter of the disclosure, a transmitter may encode M uncoded packets into N coded packets and the transmitter may then sequentially transmit all or a portion of the coded packets (based on configuration) only to a group of receivers in its coverage. In some embodiments, when the transmitter transmits N packets for a first transmission and the single ACK/NACK criterion is utilized for each transmitted packet at the receiver side for feedback of the HARQ acknowledgement to the transmitter, it may either sequentially transmit the N packets at each available opportunity or start retransmission when more than Q NACKs have been received and all of the N packets have been sent out. When the transmitter transmits N packets for a first transmission and the single packet ACK/NACK criterion is utilized for all N transmitted packets at the receiver side for feedback of the HARQ acknowledgement to the transmitter, it may either sequentially transmit the N packets at each available opportunity or start retransmission when any NACK is received and all of the N packets have been sent out. When the transmitter transmits K (less than N) packets for a first transmission and the single packet ACK/NACK feedback mechanism is utilized at the receiver side for feedback of the HARQ acknowledgement to the transmitter, it may start transmission/retransmission based on ACK/NACK feedback status when all of the K packets have been sent out. When the transmitter transmits K (K<N) packets for a first transmission and the multiple ACK/NACK feedback mechanism in one-shot is applied to the receiver side for feedback of the HARQ acknowledgement to the transmitter, it may start transmission/retransmission based on ACK/NACK feedback status when all of the K packets have been sent out. Generally, the transmitter in transmission/retransmission may cyclically and sequentially retransmit the N packets at each available opportunity. In some embodiments, only for the failure decoded packets, the transmitter may determine which packet or packets should be retransmitted with higher priority for efficiently solving and correcting error packets in many receiver-ends with the assistance of feedback information (such as ACK and NACK) from variant receivers in group communication, wherein the transmitter could choose to retransmit the packet corresponding to the NACK, or to transmit one randomly selected packet from the N coded packets, or to transmit one packet that has not been sent in the retransmission with the assistance of feedback information from variant receivers in group communication. The receiver may feedback ACK/NACK information to the transmitter when each coded packet is received and decoded, wherein the ACK/NACK information is a single-packet to represent if the received packets can be successfully decoded. The receiver may feedback ACK/NACK information to the transmitter only when all or a portion of coded packets have been sent out from the transmitter side, where the ACK/NACK bits may be by single-packet, or multiple-packet which is less than N-packet, or N-packet to represent if the receiver could successful decode N−Q packets from the received packets for the single ACK/NACK case, or a subgroup of total received packets for the multiple ACK/NACK case, or the newly received N packets for N-packet ACK/NACK case. In some embodiments, the receiver may further determine whether current or newly received packets should be fed to a HARQ buffer (not shown) for HARQ processing or considered as a non-retransmitted packet based on information from the transmitter (such as downlink control information). Therefore, transmission reliability can be efficiently improved, and retransmission overhead can be reduced.

Methods for data transmission management in a transmitter of a data transmission management system thereof, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine, such as a computer, the machine thereby becomes an apparatus for practicing the methods. The methods may also be embodied in the form of a program code transmitted over some transmission medium, such as electrical wiring or cabling, through fiber optics, or via any other form of transmission, wherein, when the program code is received and loaded into and executed by a machine, such as a computer, the machine becomes an apparatus for practicing the disclosed methods. When implemented on a general-purpose processor, the program code combines with the processor to provide a unique apparatus that operates analogously to application specific logic circuits.

While the disclosure has been described by way of example and in terms of exemplary embodiment, it is to be understood that the disclosure is not limited thereto. Those who are skilled in this technology can still make various alterations and modifications without departing from the scope and spirit of this disclosure. Therefore, the scope of the present disclosure shall be defined and protected by the following claims and their equivalents.

What is claimed is:

1. A method for data transmission management used in a transmitter, comprising:
encoding M uncoded packets into N coded packets with Q-packet error correction capability using concatenated encoding, wherein the M uncoded packets are first encoded by a first encoding scheme and then encoded into N coded packets by a second encoding scheme and where M≦N, and Q≧1;
sequentially transmitting a set or all of the N coded packets to the at least one receiver;
receiving at least one feedback information from the at least one receiver, wherein the at least one feedback information comprises at least one acknowledgment (ACK) or negative acknowledgment (NACK) information for indicating decoding statuses of the transmitted coded packets, each of the transmitted coded packets having one of the decoding statuses corresponding thereto; and
determining whether to perform a retransmission procedure to retransmit a dedicated packet to the at least one receiver according to collected ACK/NACK included in the feedback information.

2. The method as claimed in claim 1, wherein the retransmission procedure is not performed until the set or all of the N coded packets have been transmitted.

3. The method as claimed in claim 2, wherein the dedicated packet is a packet selected from any of N coded packets.

4. The method as claimed in claim 3, wherein the feedback information includes a plurality of bits for all of the transmitted packets, when the feedback criterion applied to the at least one receiver is a multiple ACK/NACK criterion and the determining step further comprises:
determining to perform the retransmission procedure to retransmit the selected packet when the number of collected NACK information from one of the at least one receiver included in the feedback information is larger than a first predetermined value,
wherein the at least one receiver does not report the feedback information immediately once receiving one of the set or all of the N coded packets.

5. The method as claimed in claim 4, further comprising:
stopping the transmission of packets to the at least one receiver when the minimum number of the number of collected ACK among all of the at least one receiver is larger than the first predetermined value or when the maximum number of the number of collected NACK among all of the at least one receiver is less than a second predetermined value.

6. The method as claimed in claim 4, further comprising:
stopping the transmission of packets to the at least one receiver when a predetermined maximum number of retransmissions have been reached.

7. The method as claimed in claim 2, wherein the feedback information comprises an ACK or NACK information for indicating whether the M uncoded packets has been successfully decoded from each of the at least one receiver, and the retransmission procedure is performed when the feedback information with the NACK information from one of the at least one receiver has been detected or stopped when the feedback information with the ACK information from all of the at least one receiver have been detected or the predetermined maximum number of retransmissions have been reached.

8. The method as claimed in claim 7, wherein the dedicated packet is a packet selected from any of N coded packets.

9. The method as claimed in claim 4, wherein the determining step further comprises:
determining to perform the retransmission procedure to retransmit the dedicated packet selected from an intersection set of error packets of all of the at least one receiver when the intersection among the error packets of each of the at least one receiver is not empty and the number of collected NACKs included in the feedback information for any of the at least one receiver is larger than a predetermined value.

10. The method as claimed in claim 9, wherein the determining step further comprises:
when the intersection among the error packets of each of the at least one receiver is empty, determining to perform the retransmission procedure to retransmit the dedicated packet selected from a union set of error packets of all of the at least one receiver or from an un-transmitted set which is a set of packets not transmitted.

11. The method as claimed in claim 1, further comprising:
sequentially receiving a plurality of feedback information corresponding to the transmitted coded packets from the at least one receiver in response to a transmission order of the transmitted coded packets.

12. The method as claimed in claim 11, wherein the determining step further comprises:
determining whether to perform the retransmission procedure to retransmit the dedicated packet to the at least one receiver according to collected ACK or NACK information included in the previously received feedback information before the set or all of the N coded packets have been transmitted.

13. A data transmission management system, comprising:
at least one receiver; and
a transmitter wirelessly connected to the at least one receiver, encoding M uncoded packets into N coded packets with Q-packet error correction capability using concatenated encoding, wherein the M uncoded packets are first encoded by a first encoding scheme and then encoded into N coded packets by a second encoding scheme and where M≦N, and Q≧1, sequentially transmitting a set or all of the N coded packets to the at least one receiver, receiving at least one feedback information from the at least one receiver, wherein the at least one feedback information comprises at least one acknowledgment (ACK) or negative acknowledgment (NACK) information for indicating decoding statuses of the transmitted coded packets, each of the transmitted coded packets having one of the decoding statuses corresponding thereto, and determining whether to perform a retransmission procedure to retransmit a dedicated packet to the at least one receiver according to collected ACK/NACK included in the feedback information.

14. The data transmission management system as claimed in claim 13, wherein the retransmission procedure is not performed by the transmitter until the set or all of the N coded packets have been transmitted.

15. The data transmission management system as claimed in claim 14, wherein the feedback information includes a plurality of bits for all of the transmitted packets, when the feedback criterion applied to the at least one receiver is a multiple ACK/NACK criterion and the transmitter further determines to perform the retransmission procedure to retransmit the selected packet when the number of collected NACK information from one of the at least one receiver included in the feedback information is larger than a first predetermined value,
wherein the at least one receiver does not report the feedback information immediately once receiving one of the set or all of the N coded packets.

16. The data transmission management system as claimed in claim 15, wherein the transmitter further stops the transmission of packets to the at least one receiver when the minimum number of the number of collected ACK among all of the at least one receiver is larger than the first predetermined value or when the maximum number of the number of collected NACK among all of the at least one receiver is less than a second predetermined value.

17. The data transmission management system as claimed in claim 14, wherein the feedback information comprises an ACK or NACK information for indicating whether the M uncoded packets has been successfully decoded from each of the at least one receiver, and the retransmission procedure is performed when the feedback information with the NACK information from one of the at least one receiver has been detected or stopped when the feedback information with the ACK information from all of the at least one receiver have been detected or the predetermined maximum number of retransmissions have been reached.

18. The data transmission management system as claimed in claim 16, wherein the transmitter further determines to perform the retransmission procedure to retransmit the dedicated packet selected from an intersection set of error packets of all of the at least one receiver when the intersection among the error packets of each of the at least one receiver is not empty and the number of collected NACKs included in the feedback information for any of the at least one receiver is larger than a predetermined value.

19. The data transmission management system as claimed in claim 18, wherein the transmitter further determines to perform the retransmission procedure to retransmit the dedicated packet selected from a union set of error packets of all of the at least one receiver or from an un-transmitted set which is a set of packets not transmitted when the intersection among the error packets of each of the at least one receiver is empty.

20. The data transmission management system as claimed in claim 13, wherein the transmitter further sequentially receives a plurality of feedback information corresponding to the transmitted coded packets from the at least one receiver in response to a transmission order of the transmitted coded packets, and determines whether to perform the retransmission procedure to retransmit the dedicated packet to the at least one receiver according to collected ACK or NACK information included in the previously received feedback information before the set or all of the N coded packets have been transmitted.
